(19) United States
(12) Patent Application Publication
(10) Pub. No.: US 2024/0235512 A9
(43) Pub. Date: Jul. 11, 2024

(54) MICRO-ELECTRO-MECHANICAL SYSTEM DEVICE AND PIEZOELECTRIC COMPOSITE STACK THEREOF

(71) Applicant: Vanguard International Semiconductor Corporation, Hsinchu (TW)

(72) Inventors: JIA JIE XIA, Singapore (SG); BEVITA KALLUPALATHINKAL CHANDRAN, Singapore (SG); RANGANATHAN NAGARAJAN, Singapore (SG); RAMACHANDRAMURTHY PRADEEP YELEHANKA, Singapore (SG)

(73) Assignee: Vanguard International Semiconductor Corporation, Hsinchu (TW)

(21) Appl. No.: 17/968,812

(22) Filed: Oct. 19, 2022

(51) Int. Cl. H03H 3/02; B81B 7/02; H04R 19/00

(52) U.S. Cl. CPC H03H 3/02; B81B 7/02; H04R 19/005; H03H 2003/021; H04R 2201/003

(57) ABSTRACT

A micro-electro-mechanical system (MEMS) device includes a substrate having a cavity and a MEMS structure disposed over the cavity and attached to the substrate. The MEMS structure includes at least one first piezoelectric layer having a first piezoelectric coefficient and two second piezoelectric layers respectively disposed under and above the first piezoelectric layer, where each second piezoelectric layer has a second piezoelectric coefficient higher than the first piezoelectric coefficient. The MEMS structure further includes a first electrode layer and a second electrode layer sandwiching the two second piezoelectric layers.

### BACKGROUND OF THE INVENTION

### 1. Field of the Invention

The present disclosure relates generally to micro-electro-mechanical system (MEMS) devices, and more particularly to a piezoelectric composite stack of the MEMS devices.

### 2. Description of the Prior Art

Micro-electro-mechanical systems (MEMS) devices are microscopic devices that integrate mechanical and electrical components to sense physical quantities and/or to interact with the surrounding environment. The microscopic devices include both the electronic and mechanical function which is operated based on, for instance, electromagnetic, electrostrictive, thermoelectric, piezoelectric, or piezoresistive effects. Therefore, the MEMS devices are often applied to microelectronics such as piezoelectric micromachined ultrasonic transducer (PMUT), accelerometer, gyroscope, timing device, acoustic filter, etc.

The conventional PMUT has a membrane consisting of a homogeneous piezoelectric material and electrodes. During the operation of the PMUT, an ultrasound wave generated by vibrating the membrane is transmitted from the PMUT to an object, and then the reflected wave generating after hitting the object could be detected by the PMUT. However, the membrane consisting of the homogeneous piezoelectric material has lower sensitivity of the PMUT. Accordingly, there is a need to improve the sensitivity of the conventional PMUT.

### SUMMARY OF THE INVENTION

In view of this, embodiments of the present disclosure provide MEMS devices and piezoelectric composite stacks thereof to improve the sensitivity of the MEMS devices. The MEMS devices of the present disclosure include a piezoelectric composite stack of a MEMS structure. The piezoelectric composite stack includes two outer piezoelectric layers having a higher piezoelectric coefficient sandwiching an inner piezoelectric layer having a lower piezoelectric coefficient. The outer piezoelectric layers having the higher piezoelectric coefficient can generate more charges on the top and bottom surfaces of the piezoelectric composite stack, thereby improving the sensitivity of the MEMS devices.

According to one embodiment of the present disclosure, a MEMS device is provided and includes a substrate having a cavity and a MEMS structure disposed over the cavity and attached to the substrate. The MEMS structure includes at least one first piezoelectric layer having a first piezoelectric coefficient and two second piezoelectric layers respectively disposed under and above the first piezoelectric layer, where each of the second piezoelectric layers has a second piezoelectric coefficient higher than the first piezoelectric coefficient. In addition, the MEMS structure further includes a first electrode layer and a second electrode layer sandwiching the two second piezoelectric layers.

According to one embodiment of the present disclosure, a piezoelectric composite stack of a MEMS device is provided and includes at least one piezoelectric film and a plurality of electrode layers. The number of the at least one piezoelectric film is an integer (n), and the number of the plurality of electrode layers is n+1. Two of the plurality of electrode layers sandwich one of the at least one piezoelectric film. Each of the at least one piezoelectric film includes a lower piezoelectric coefficient layer having a first piezoelectric coefficient and at least one higher piezoelectric coefficient layer stacked with the lower piezoelectric coefficient layer and having a second piezoelectric coefficient higher than the first piezoelectric coefficient.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 shows a schematic cross-sectional diagram of a MEMS device according to one embodiment of the present disclosure.

FIG. 2 shows a schematic cross-sectional diagram of a MEMS device according to another embodiment of the present disclosure.

FIG. 3 shows a schematic cross-sectional diagram of a MEMS device according to further another embodiment of the present disclosure.

FIG. 4 shows a schematic cross-sectional diagram of a piezoelectric composite stack according to one embodiment of the present disclosure.

FIG. 5 shows a schematic cross-sectional diagram of a piezoelectric composite stack according to another embodiment of the present disclosure.

FIG. 6 shows a schematic cross-sectional diagram of a piezoelectric composite stack according to further another embodiment of the present disclosure.

FIG. 7 and FIG. 8 show schematic cross-sectional diagrams of several stages of a method of fabricating a MEMS device according to one embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.50 of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS devices and piezoelectric composite stacks thereof. The piezoelectric composite stack is used for forming a MEMS structure and includes two outer higher piezoelectric coefficient layers sandwiching an inner lower piezoelectric coefficient layer. During the operation of the MEMS devices, max stress usually occurs at the top and bottom surfaces of the MEMS structure. The outer higher piezoelectric coefficient layers can generate more charges on the top and bottom surfaces of the piezoelectric composite stack, thereby improving the sensitivity of the MEMS devices. In addition, the inner lower piezoelectric coefficient layer has less local stress problem than the outer higher piezoelectric coefficient layers and no cone shape crystal defect issue. Moreover, in the embodiments of the present disclosure, the inner lower piezoelectric coefficient layer has a thickness greater than a total thickness of the outer higher piezoelectric coefficient layers, thereby providing a better mechanical strength for supporting the piezoelectric composite stack. Furthermore, the inner lower piezoelectric coefficient layer has lower noise, thereby enhancing the performance of the MEMS devices.

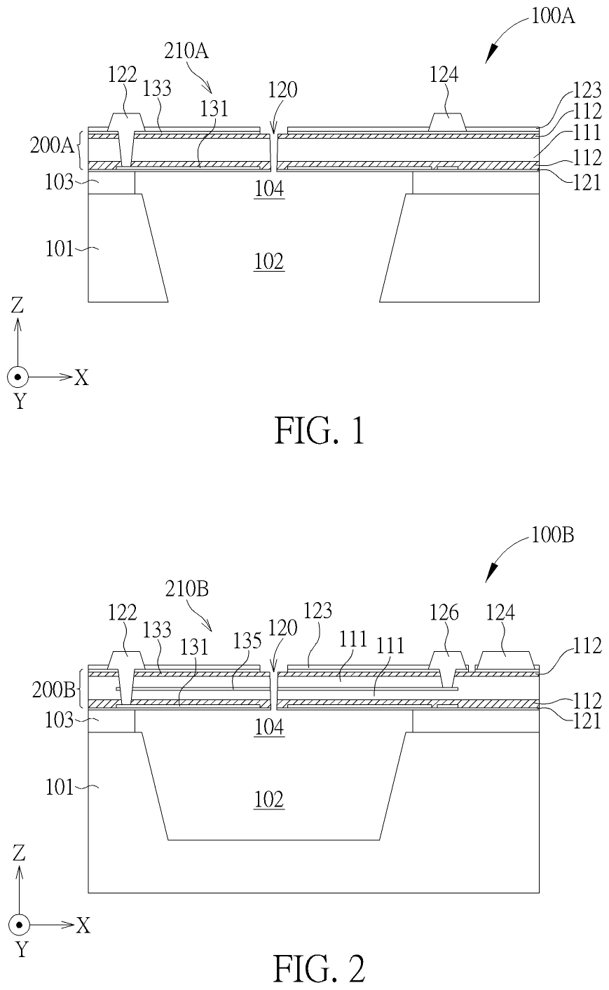

FIG. 1 shows a schematic cross-sectional diagram of a MEMS device 100A according to one embodiment of the present disclosure. Referring to FIG. 1, the MEMS device 100A includes a substrate 101 having a cavity 102. The substrate 101 may be a semiconductor substrate, for example a silicon (Si) wafer or other suitable semiconductor wafer. In some embodiments, the cavity 102 may penetrate the substrate 101. In some other embodiments, the cavity 102 may not penetrate the substrate 101 and is extended from a front surface of the substrate 101 to a position in the thickness of the substrate 101, where the front surface of the substrate 101 is adjacent to a MEMS structure 210A. In one embodiment, the MEMS structure 210A of the MEMS device 100A is formed from a piezoelectric composite stack 200A.

As shown in FIG. 1, the piezoelectric composite stack 200A includes a first piezoelectric layer 111 and two second piezoelectric layers 112 respectively disposed under and above the first piezoelectric layer 111. For example, the two second piezoelectric layers 112 are respectively disposed on a top surface and a bottom surface of the first piezoelectric layer 111. In an embodiment, the first piezoelectric layer 111 has a first piezoelectric coefficient and the two second piezoelectric layers 112 have a second piezoelectric coefficient higher than the first piezoelectric coefficient. In another embodiment, the first piezoelectric layer 111 has a first piezoelectric coefficient and the two second piezoelectric layers 112 respectively have a second piezoelectric coefficient and a third piezoelectric coefficient that are higher than the first piezoelectric coefficient. In some embodiments, the material of the first piezoelectric layer 111 is for example aluminum nitride (AlN), zinc oxide (ZnO), or gallium nitride (GaN). The material of the two second piezoelectric layers 112 is for example lead zirconate titanate (PZT), or AlN, ZnO or GaN doped with a dopant, where the dopant is for example scandium (Sc), yttrium (Y), titanium (Ti), chromium (Cr), magnesium (Mg) or hafnium (Hf). The two second piezoelectric layers 112 may have the same composition. Alternatively, the two second piezoelectric layers 112 may have different compositions from each other.

In addition, the piezoelectric composite stack 200A includes a first electrode layer 131 and a second electrode layer 133 sandwiching the two second piezoelectric layers 112. For example, the first electrode layer 131 is disposed on the bottom surface of the lower second piezoelectric layer 112, and the second electrode layer 133 is disposed on the top surface of the upper second piezoelectric layer 112. In some embodiments, the material of the first electrode layer 131 and the second electrode layer 133 may be Mo, Al, Pt, Ru, Ti, other suitable conductive material, or a combination thereof. The MEMS structure 210A of the MEMS device 100A is formed from the piezoelectric composite stack 200A and further includes a first contact pad 122 disposed on the second electrode layer 133 and electrically coupled to the first electrode layer 131 through a via that passes through the two second piezoelectric layers 112 and the first piezoelectric layer 111. The MEMS structure 210A further includes a second contact pad 124 disposed on and electrically coupled to the second electrode layer 133. The electrical signals produced from the second piezoelectric layers 112 may be transmitted to an outer circuit through the electrode layers 131 and 133 and the contact pads 122 and 124. In some embodiments, the material of the first contact pad 122 and the second contact pad 124 may be AlCu or other suitable conductive material.

As shown in FIG. 1, in one embodiment, the MEMS structure 210A further includes a seed layer 121 disposed on the bottom surface of the first electrode layer 131, and a passivation layer 123 disposed on the top surface of the second electrode layer 133. In some embodiments, the materials of the seed layer 121 and the passivation layer 123 may be AlN, SiO₂ or SiON, but not limited thereto. The first contact pad 122 and the second contact pad 124 may pass through the passivation layer 123 to be electrically connected to the second electrode layer 133. In addition, the MEMS structure 210A includes an interrupted portion 120 penetrating the MEMS structure 210A. For example, the interrupted portion 120 penetrates the passivation layer 123, the piezoelectric composite stack 200A and the seed layer 121. The interrupted portion 120 is disposed above the cavity 102, thereby forming a cantilevered beam or a cantilevered diaphragm of the MEMS structure 210A.

In addition, the MEMS device 100A further includes a sacrificial layer 103 disposed between the substrate 101 and the MEMS structure 210A. The sacrificial layer 103 has an opening 104 connected to the interrupted portion 120 and the cavity 102. The width of the opening 104 in an X-axial direction may be larger than the width of the cavity 102. In some embodiments, the material of the sacrificial layer 103 may be SiO₂ or other suitable dielectric material. In this embodiment, the stack of the piezoelectric layers and the electrode layers in the MEMS structure 210A is symmetric with respect to a horizontal plane (for example a XY plane) in the middle of the first piezoelectric layer 111.

In some embodiments, a fixed end of the cantilevered beam or the cantilevered diaphragm of the MEMS device 100A is adjacent to the sacrificial layer 103 or the substrate 101, and a free end of the cantilevered beam or the cantilevered diaphragm of the MEMS device 100A is adjacent to the interrupted portion 120. During the operation of the MEMS device 100A, when sound waves exerts acoustic pressure on or electrical signals are applied to the MEMS structure 210A, the cantilevered beam or the cantilevered diaphragm of the MEMS structure 210A may vibrate and a max stress occurs close to the fixed end and at the top and bottom surfaces of MEMS structure 210A. According to the embodiments of the present disclosure, the higher piezoelectric coefficient layers such as the second piezoelectric layers 112 are disposed on the top surface and the bottom surface of the piezoelectric composite stack 200A, thereby generating more piezoelectric charges in the MEMS structure 210A to improve the sensitivity of the MEMS device 100A.

FIG. 2 shows a schematic cross-sectional diagram of a MEMS device 100B according to another embodiment of the present disclosure. As shown in FIG. 2, a piezoelectric composite stack 200A of the MEMS device 100B includes two first piezoelectric layers 111 disposed between the two second piezoelectric layers 112. The thickness of each first piezoelectric layer 111 is greater than the thickness of each second piezoelectric layer 112. The piezoelectric composite stack 200A further includes a third electrode layer 135 disposed between the two first piezoelectric layers 111. The material of the third electrode layer 135 may be the same as that of the first electrode layer 131 and the second electrode layer 133. The two first piezoelectric layers 111 have an average piezoelectric coefficient lower than the second piezoelectric coefficient of the second piezoelectric layer 112. In some embodiments, each first piezoelectric layer 111 has a first piezoelectric coefficient lower than the second piezoelectric coefficient of each second piezoelectric layer 112. The two first piezoelectric layers 111 may have the same composition. Alternatively, the compositions of the two first piezoelectric layers 111 may be different from each other. In this embodiment, the materials of the first piezoelectric layers 111, the second piezoelectric layers 112, the first electrode layer 131, the second electrode layer 133 and the third electrode layer 135 may refer to the aforementioned descriptions of piezoelectric layers and electrode layers in FIG. 1. In addition, a MEMS structure 210B of the MEMS device 100B further includes a third contact pad 126 disposed on the first electrode layer 131 and electrically coupled to the third electrode layer 135.

As shown in FIG. 2, in one embodiment, the cavity 102 is formed on a front surface of the substrate 101 and extended from the front surface to a position in the thickness of the substrate 101, not penetrating the substrate 101. The details of other features of the MEMS device 100B such as the seed layer 121, the passivation layer 123 and the sacrificial layer 103 may refer to the aforementioned descriptions of FIG. 1. In this embodiment, the stack of the piezoelectric layers and the electrode layers in the MEMS structure 210B is symmetric with respect to the third electrode layer 135. According to the embodiments of the present disclosure, the higher piezoelectric coefficient layers such as the second piezoelectric layers 112 are disposed on the top surface and the bottom surface of the piezoelectric composite stack 200B, thereby generating more piezoelectric charges in the MEMS structure 210B to improve the sensitivity of the MEMS device 100B. Moreover, the electrical signals produced from the two first piezoelectric layers 111 are transmitted through the third electrode layer 135 and the third contact pad 126 to enhance the sensitivity of the MEMS device 100B.

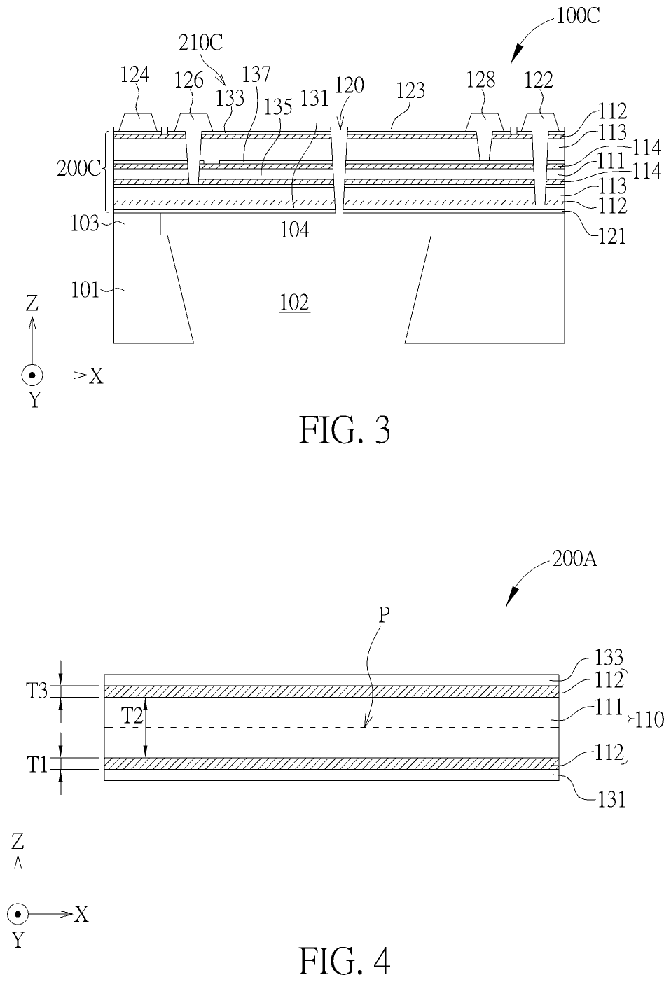

FIG. 3 shows a schematic cross-sectional diagram of a MEMS device 100C according to further another embodiment of the present disclosure. As shown in FIG. 3, a piezoelectric composite stack 200C of the MEMS device 100C includes two third piezoelectric layers 113 respectively disposed under and above the first piezoelectric layer 111. The two third piezoelectric layers 113 are disposed between the two second piezoelectric layers 112 and have an average piezoelectric coefficient lower than the second piezoelectric coefficient of the second piezoelectric layers 112. The piezoelectric composite stack 200C further includes two fourth piezoelectric layers 114 sandwiching the first piezoelectric layer 111 and having an average piezoelectric coefficient higher than the first piezoelectric coefficient of the first piezoelectric layer 111. Moreover, the piezoelectric coefficient of each third piezoelectric layer 113 is lower than the piezoelectric coefficient of each fourth piezoelectric layer 114. In some embodiments, the materials of the first piezoelectric layer 111 and the third piezoelectric layers 113 may be selected from AlN, ZnO and GaN. The materials of the first piezoelectric layer 111 and the third piezoelectric layers 113 may be the same as or different from each other. The materials of the second piezoelectric layers 112 and the fourth piezoelectric layers 114 may be selected from lead zirconate titanate (PZT), doped AlN, doped ZnO and doped GaN, where the dopant may be Sc, Y, Ti, Cr, Mg or Hf. The materials of the second piezoelectric layers 112 and the fourth piezoelectric layers 114 may be the same as or different from each other.

In addition, the piezoelectric composite stack 200C further includes a third electrode layer 135 and a fourth electrode layer 137 sandwiching the two fourth piezoelectric layers 114. For example, the third electrode layer 135 is disposed on the bottom surface of the lower fourth piezoelectric layer 114, and the fourth electrode layer 137 is disposed on the top surface of the upper fourth piezoelectric layer 114. The materials of the first electrode layer 131, the second electrode layer 133, the third electrode layer 135 and the fourth electrode layer 137 may be Mo, Al, Pt, Ru, Ti, other suitable conductive material, or a combination thereof. A MEMS structure 210C of the MEMS device 100C further includes a fourth contact pad 128 disposed on the first electrode layer 131 and electrically coupled to the fourth electrode layer 137. The material of the fourth contact pad 128 may be AlCu or other suitable conductive material. In this embodiment, the stack of the piezoelectric layers and the electrode layers in the MEMS structure 210C is symmetric with respect to a horizontal plane (for example a XY plane) in the middle of the first piezoelectric layer 111. The details of other features of the MEMS device 100C such as the seed layer 121, the passivation layer 123, the sacrificial layer 103, the piezoelectric layers 111 and 112, the electrode layers 131, 133 and 135, and the contact pads 122, 124 and 126 may refer to the aforementioned descriptions of FIG. 1 and FIG. 2.

According to the embodiments of the present disclosure, the higher piezoelectric coefficient layers such as the second piezoelectric layers 112 are disposed on the top surface and the bottom surface of the piezoelectric composite stack 200C, thereby generating more piezoelectric charges in the MEMS structure 210C to improve the sensitivity of the MEMS device 100C. Moreover, the electrical signals produced from the other higher piezoelectric coefficient layers such as the two fourth piezoelectric layers 114 are transmitted through the third electrode layer 135, the fourth electrode layer 137, the third contact pad 126 and the fourth contact pad 128 to further improve the sensitivity of the MEMS device 100C.

In addition, according to the embodiments of the present disclosure, a piezoelectric composite stack of a MEMS device includes one or more piezoelectric film(s) and multiple electrode layers. The number of the piezoelectric film(s) is an integer (n), and the number of the electrode layers is n+1. Each piezoelectric film is sandwiched by two of the electrode layers. In addition, each piezoelectric film includes a lower piezoelectric coefficient layer having a first piezoelectric coefficient and at least one higher piezoelectric coefficient layer stacked with the lower piezoelectric coefficient layer and having a second piezoelectric coefficient higher than the first piezoelectric coefficient.

In some embodiments, the number of n is equal to 2a, where a is an integer greater than zero (for example, a=1, 2, 3, 4, etc.). The number of the lower piezoelectric coefficient layers of the piezoelectric composite stack is an integer (i) that is equal to n, and the number of the higher piezoelectric coefficient layers of the piezoelectric composite stack is an integer (j) that is equal to n.

In some other embodiments, the number of n is equal to 2a-1, where a is an integer greater than zero (for example, a=1, 2, 3, 4, etc.). The number of the lower piezoelectric coefficient layer(s) of the piezoelectric composite stack is an integer (i) that is equal to n, and the number of the higher piezoelectric coefficient layers of the piezoelectric composite stack is an integer (j) that is equal to n+1.

In one embodiment, the number of the piezoelectric film is 1, the number of the lower piezoelectric coefficient layer is 1, and the number of the higher piezoelectric coefficient layers is 2. FIG. 4 shows a schematic cross-sectional diagram of a piezoelectric composite stack 200A according to one embodiment of the present disclosure. Referring to FIG. 4, the piezoelectric composite stack 200A includes one piezoelectric film 110. The piezoelectric film 110 includes two higher piezoelectric coefficient layers 112 (also referred to as the second piezoelectric layers) respectively stacked above and under one lower piezoelectric coefficient layer 111 (also referred to as the first piezoelectric layer). The bottom higher piezoelectric coefficient layer 112 has a thickness T1. The lower piezoelectric coefficient layer 111 has a thickness T2. The top higher piezoelectric coefficient layer 112 has a thickness T3. The total thickness of the higher piezoelectric coefficient layers 112 is less than 50% of the total thickness of the piezoelectric film 110, i.e., T1+T3<0.5*(T1+T2+T3). The thickness T2 is greater than each of the thicknesses T1 and T3. The thicknesses T1 and T3 may be the same as or different from each other.

The piezoelectric composite stack 200A further includes two electrode layers 131 and 133 sandwiching the piezoelectric film 110. The piezoelectric composite stack 200A may be symmetric with respect to a horizontal plane P in the middle of the piezoelectric composite stack 200A, i.e., the middle of the lower piezoelectric coefficient layer 111.

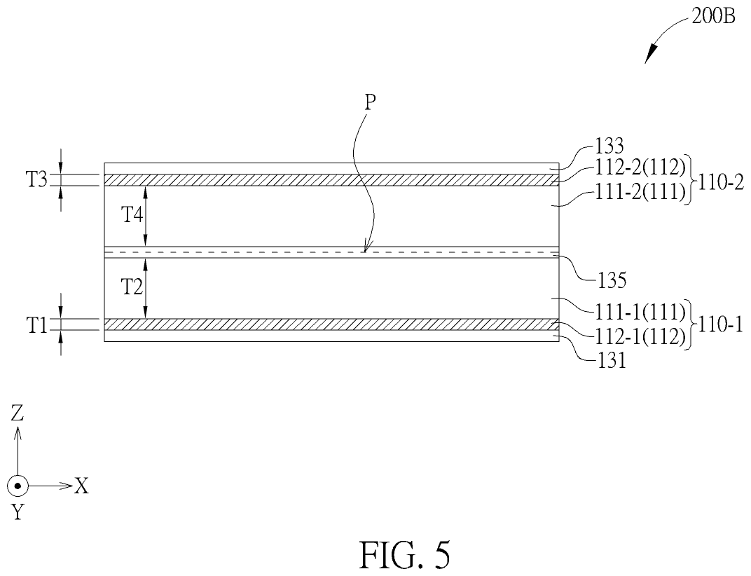

In one embodiment, the number of the piezoelectric film is 2, the number of the lower piezoelectric coefficient layer is 2, and the number of the higher piezoelectric coefficient layers is 2. FIG. 5 shows a schematic cross-sectional diagram of a piezoelectric composite stack 200B according to one embodiment of the present disclosure. Referring to FIG. 5, the piezoelectric composite stack 200A includes a lower piezoelectric film 110-1 and an upper piezoelectric film 110-2. The lower piezoelectric film 110-1 includes a (1-2)-th higher piezoelectric coefficient layer 112-1 stacked under a (1-1)-th lower piezoelectric coefficient layer 111-1. The upper piezoelectric film 110-2 includes a (2-2)-th higher piezoelectric coefficient layer 112-2 stacked above a (2-1)-th lower piezoelectric coefficient layer 111-2. In one embodiment, the (2-2)-th and the (1-2)-th higher piezoelectric coefficient layers have a second piezoelectric coefficient and may be referred to as the second piezoelectric layers 112. The (2-1)-th and the (1-1)-th lower piezoelectric coefficient layers have a first piezoelectric coefficient lower than the second piezoelectric coefficient and may be referred to as the first piezoelectric layers 111.

The higher piezoelectric coefficient layer 112-1 has a thickness T1. The lower piezoelectric coefficient layer 111-1 has a thickness T2. The higher piezoelectric coefficient layer 112-2 has a thickness T3. The lower piezoelectric coefficient layer 111-2 has a thickness T4. The thickness T1 is less than 50% of the total thickness of the lower piezoelectric film 110-1, i.e., T1<0.5*(T1+T2). The thickness T3 is less than 50% of the total thickness of the upper piezoelectric film 110-2, i.e., T3<0.5*(T3+T4). The thickness T2 is greater the thickness T1. The thickness T4 is greater the thickness T3. In addition, the thicknesses T1 and T3 may be the same as or different from each other. The thicknesses T2 and T4 may be the same as or different from each other.

The piezoelectric composite stack 200B further includes three electrode layers 131, 133 and 135. The electrode layers 131 and 135 sandwich the lower piezoelectric film 110-1. The electrode layers 133 and 135 sandwich the upper piezoelectric film 110-2. The electrode layer 135 is disposed between the upper piezoelectric film 110-2 and the lower piezoelectric film 110-1. The piezoelectric composite stack 200A may be symmetric with respect to a horizontal plane Pin the middle of the piezoelectric composite stack 200B, i.e., the middle of the electrode layer 135.

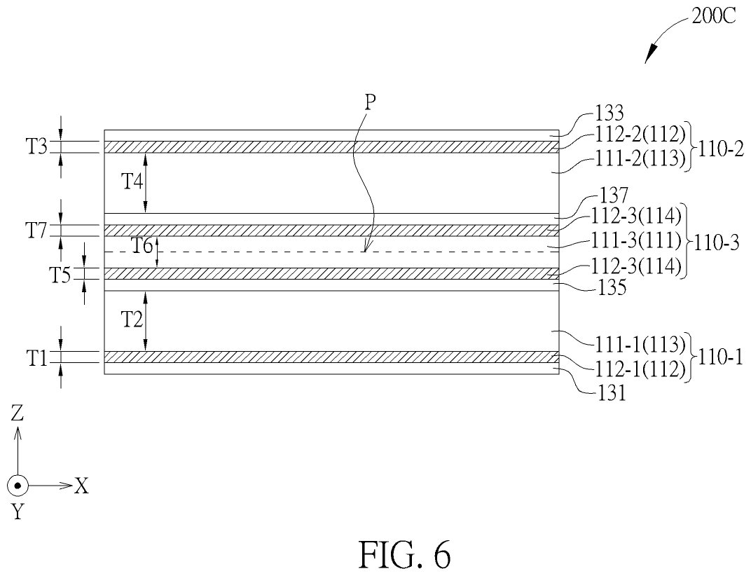

In one embodiment, the number of the piezoelectric film is 3, the number of the lower piezoelectric coefficient layer is 3, and the number of the higher piezoelectric coefficient layers is 4. FIG. 6 shows a schematic cross-sectional diagram of a piezoelectric composite stack 200C according to one embodiment of the present disclosure. Referring to FIG. 6, the piezoelectric composite stack 200C includes a lower piezoelectric film 110-1, an upper piezoelectric film 110-2 and a middle piezoelectric film 110-3. The lower piezoelectric film 110-1 includes a (1-2)-th higher piezoelectric coefficient layer 112-1 stacked under a (1-1)-th lower piezoelectric coefficient layer 111-1. The upper piezoelectric film 110-2 includes a (2-2)-th higher piezoelectric coefficient layer 112-2 stacked above a (2-1)-th lower piezoelectric coefficient layer 111-2. The middle piezoelectric film 110-3 includes two (3-2)-th higher piezoelectric coefficient layers 112-3 sandwiching a (3-1)-th lower piezoelectric coefficient layer 111-3. In one embodiment, the (2-2)-th and the (1-2)-th higher piezoelectric coefficient layers have a second piezoelectric coefficient and may be referred to as the second piezoelectric layers 112. The (3-2)-th higher piezoelectric coefficient layers have a fourth piezoelectric coefficient and may be referred to as the fourth piezoelectric layers 114. In one embodiment, the fourth piezoelectric coefficient is the same as the second piezoelectric coefficient. The (3-1)-th lower piezoelectric coefficient layer has a first piezoelectric coefficient lower and may be referred to as the first piezoelectric layer 111. The first piezoelectric coefficient is lower than the second and the fourth piezoelectric coefficients. The (2-1)-th and the (1-1)-th lower piezoelectric coefficient layers have a third piezoelectric coefficient and may be referred to as the third piezoelectric layers 113. In one embodiment, the third piezoelectric coefficient is the same as the first piezoelectric coefficient. The third piezoelectric coefficient is lower than the second and the fourth piezoelectric coefficients.

The higher piezoelectric coefficient layer 112-1 has a thickness T1. The lower piezoelectric coefficient layer 111-1 has a thickness T2. The higher piezoelectric coefficient layer 112-2 has a thickness T3. The lower piezoelectric coefficient layer 111-2 has a thickness T4. The two higher piezoelectric coefficient layers 112-3 respectively have a thickness T5 and a thickness T7. The lower piezoelectric coefficient layer 111-3 has a thickness T6. The thickness T1 is less than 50% of the total thickness of the lower piezoelectric film 110-1, i.e., T1<0.5*(T1+T2). The thickness T3 is less than 50% of the total thickness of the upper piezoelectric film 110-2, i.e., T3<0.5*(T3+T4). The total thickness of T5 and T7 is less than 50% of the total thickness of the middle piezoelectric film 110-3, i.e., T5+T7<0.5*(T5+T6+T7). The thickness T2 is greater the thickness T1. The thickness T4 is greater the thickness T3. The thickness T6 is greater each of the thickness T5 and the thickness T7. In addition, the thickness of the middle piezoelectric film 110-3 is different from both the thickness of the upper piezoelectric film 110-2 and the thickness of the lower piezoelectric film 110-1, i.e., (T5+T6+T7)(T1+T2) and (T5+T6+T7)(T3+T4). Moreover, the thicknesses T5 and T7 may be the same as or different from each other. The thicknesses T1 and T3 may be the same as or different from each other. The thicknesses T2 and T4 may be the same as or different from each other. The thickness T6 may be the same as or different from each of the thicknesses T2 and T4.

The piezoelectric composite stack 200C further includes four electrode layers 131, 133, 135 and 137. The electrode layers 131 and 135 sandwich the lower piezoelectric film 110-1. The electrode layers 133 and 137 sandwich the upper piezoelectric film 110-2. The electrode layers 135 and 137 sandwich the middle piezoelectric film 110-3. The electrode layer 135 is disposed between the lower piezoelectric film 110-1 and the middle piezoelectric film 110-3. The electrode layer 137 is disposed between the upper piezoelectric film 110-2 and the middle piezoelectric film 110-3. The piezoelectric composite stack 200C may be symmetric with respect to a horizontal plane Pin the middle of the piezoelectric composite stack 200C, i.e., the middle of the lower piezoelectric coefficient layer 111-3.

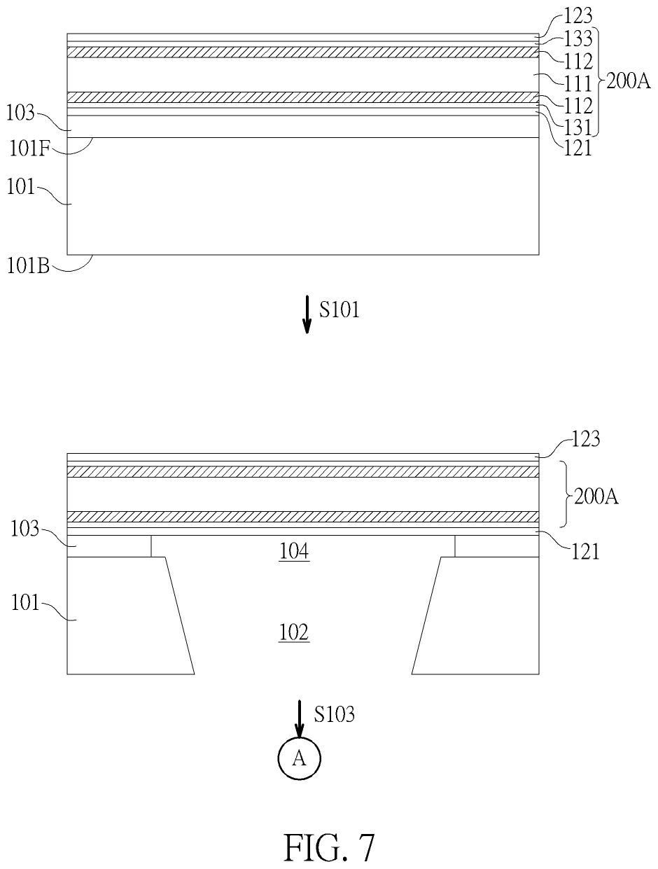

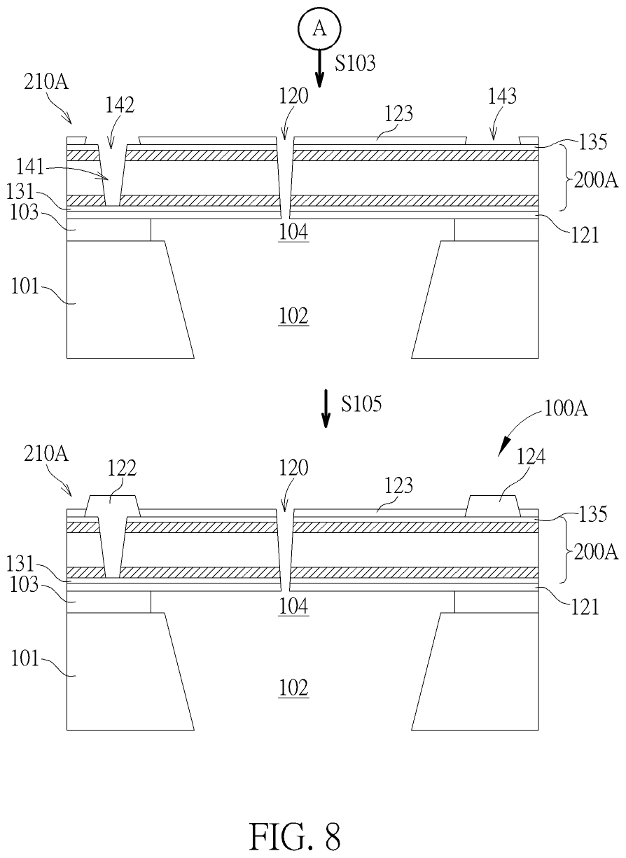

FIG. 7 and FIG. 8 show schematic cross-sectional diagrams of several stages of a method of fabricating a MEMS device 100A according to one embodiment of the present disclosure. Referring to FIG. 7, firstly, a substrate 101 such as a silicon substrate is provided. A sacrificial layer 103 such as a silicon oxide layer is then deposited on a front surface 101F of the substrate 101. Thereafter, a seed layer 121, a first electrode layer 131, a second piezoelectric layer 112, a first piezoelectric layer 111, another second piezoelectric layer 112, a second electrode layer 133 and a passivation layer 123 are formed on the sacrificial layer 103 from bottom to top in sequence. The first electrode layer 131 and the second electrode layer 133 are respectively formed by a deposition process and a patterning process. The first piezoelectric layer 111 and the second piezoelectric layers 112 are formed by an in-situ deposition process. The first electrode layer 131, the second piezoelectric layers 112, the first piezoelectric layer 111 and the second electrode layer 133 construct a piezoelectric composite stack 200A. The seed layer 121 and the passivation layer 123 are respectively formed by a deposition process. In some embodiments, the materials of the seed layer 121, the first piezoelectric layer 111 and the passivation layer 123 may be AlN. The material of the second piezoelectric layers 112 may be AlN doped with Sc, i.e., ScAlN. The materials of the first electrode layer 131 and the second electrode layer 133 may be Mo. The thickness of each second piezoelectric layer 112 may be about 50 nm to 200 nm. The thickness of the first piezoelectric layer 111 may be about 200 nm to 500 nm.

Next, still referring to FIG. 7, at step S101, the substrate 101 is etched to form a cavity 102. In one embodiment, the cavity 102 is formed to penetrate the substrate 101. In another embodiment, the cavity 102 may not penetrate the substrate 101. Furthermore, the sacrificial layer 103 is etched to form an opening 104 that is connected to the cavity 102. In a top view, the area of the opening 104 may be larger than the area of the cavity 102. For example, the width of the opening 104 may be greater than the width of the cavity 102.

Next, referring to FIG. 8, at step S103, the passivation layer 123, the piezoelectric composite stack 200A and the seed layer 121 are etched to form an interrupted portion 120, thereby forming a cantilevered beam or a cantilevered diaphragm of a MEMS structure 210A. The interrupted portion 120 penetrates the MEMS structure 210A and is located above the cavity 102. The opening 104 is connected to the interrupted portion 120 and the cavity 102. A fixed end of the cantilevered beam or diaphragm of the MEMS structure 210A is attached on the sacrificial layer 103 and the substrate 101. A free end of the cantilevered beam or diaphragm of the MEMS structure 210A is located above the opening 104 and the cavity 102. Therefore, the cantilevered beam or diaphragm of the MEMS structure 210A may vibrate when sound waves exert acoustic pressure on the MEMS structure 210A through the cavity 102 and the opening 104. In addition, at the step S103, a via hole 141 is formed in the piezoelectric composite stack 200A and stopped on the first electrode layer 131 by a photolithography and an etching processes. An opening 142 and an opening 143 are formed in the passivation layer 123 and stopped on the second electrode layer 133 by another photolithography and another etching processes. Then, still referring to FIG. 8, at step S105, a first contact pad 122 is formed in the via hole 141 and the opening 142, and a second contact pad 122 is formed in the opening 143 by a deposition process and a patterning process to complete the MEMS device 100A.

According to the embodiments of the present disclosure, the MEMS structure of the MEMS devices include two outer higher piezoelectric coefficient layers disposed on the top surface and the bottom surface of the piezoelectric composite stack. When a pressure is applied on the cantilevered beam or diaphragm of the MEMS structure, max stress occurs at the top and bottom surfaces of the cantilevered beam or diaphragm. The outer higher piezoelectric coefficient layers can generate more piezoelectric charges in the MEMS structure, thereby improving the sensitivity of the MEMS devices.

In addition, according to the embodiments of the present disclosure, the inner lower piezoelectric coefficient layer of the piezoelectric composite stack has less local stress problem than the outer higher piezoelectric coefficient layers and has no cone shape crystal defect issue, thereby providing a better mechanical strength to support the MEMS structure. Moreover, the inner lower piezoelectric coefficient layer of the piezoelectric composite stack has lower noise to enhance the sensitivity of the MEMS devices.

Furthermore, the inner lower piezoelectric coefficient layer of the piezoelectric composite stack is much cheaper than the outer higher piezoelectric coefficient layers, thereby reducing the cost of the MEMS devices. In addition, the outer higher piezoelectric coefficient layers and the inner lower piezoelectric coefficient layer of the piezoelectric composite stack may be formed by an in-situ deposition process. The formation of the piezoelectric composite stack may be integrated into the processes of fabricating the MEMS devices. Therefore, the fabrication of the MEMS devices of the present disclosure is simple.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) device, comprising:
a substrate having a cavity; and
a MEMS structure disposed over the cavity and attached to the substrate, wherein the MEMS structure comprises:
at least one first piezoelectric layer having a first piezoelectric coefficient;
two second piezoelectric layers respectively disposed under and above the first piezoelectric layer, each of the second piezoelectric layers having a second piezoelectric coefficient higher than the first piezoelectric coefficient; and
a first electrode layer and a second electrode layer sandwiching the two second piezoelectric layers.

2. The MEMS device of claim 1, wherein the MEMS structure is symmetric with respect to a horizontal plane in the middle of the at least one first piezoelectric layer.

3. The MEMS device of claim 1, wherein a thickness of the at least one first piezoelectric layer is greater than the thickness of each of the second piezoelectric layers.

4. The MEMS device of claim 1, wherein the at least one first piezoelectric layer comprises two first piezoelectric layers disposed between the two second piezoelectric layers, and having an average piezoelectric coefficient lower than the second piezoelectric coefficient, and the MEMS structure further comprises a third electrode layer disposed between the two first piezoelectric layers.

5. The MEMS device of claim 4, wherein the MEMS structure is symmetric with respect to the third electrode layer.

6. The MEMS device of claim 1, wherein the MEMS structure further comprises:
two third piezoelectric layers respectively disposed under and above the at least one first piezoelectric layer, and disposed between the two second piezoelectric layers, wherein an average piezoelectric coefficient of the two third piezoelectric layers is lower than the second piezoelectric coefficient;
two fourth piezoelectric layers sandwiching the at least one first piezoelectric layer and having an average piezoelectric coefficient higher than the first piezoelectric coefficient; and
a third electrode layer and a fourth electrode layer sandwiching the two fourth piezoelectric layers.

7. The MEMS device of claim 6, wherein the composition of the at least one first piezoelectric layer and the two third piezoelectric layers comprises aluminum nitride (AlN), zinc oxide (ZnO), or gallium nitride (GaN), and the composition of the two second piezoelectric layers and the two fourth piezoelectric layers comprises lead zirconate titanate (PZT), or AlN, ZnO or GaN doped with a dopant, and wherein the dopant comprises scandium (Sc), yttrium (Y), titanium (Ti), chromium (Cr), magnesium (Mg) or hafnium (Hf).

8. The MEMS device of claim 1, wherein the MEMS structure further comprises:
a seed layer disposed on a bottom surface of the first electrode layer; and
a passivation layer disposed on a top surface of the second electrode layer.

9. The MEMS device of claim 1, wherein the MEMS structure has an interrupted portion penetrating the MEMS structure and disposed above the cavity, and the MEMS structure comprises a cantilevered beam or a cantilevered diaphragm above the cavity.

10. The MEMS device of claim 9, further comprising a sacrificial layer disposed between the substrate and the MEMS structure, wherein the sacrificial layer has an opening connected to the interrupted portion and the cavity.

11. A piezoelectric composite stack of a micro-electro-mechanical system (MEMS) device, comprising:
at least one piezoelectric film, wherein the number of the at least one piezoelectric film is an integer (n); and
a plurality of electrode layers, wherein the number of the plurality of electrode layers is n+1, and two of the plurality of electrode layers sandwich one of the at least one piezoelectric film, and
wherein each the piezoelectric film comprises:
a lower piezoelectric coefficient layer having a first piezoelectric coefficient; and
at least one higher piezoelectric coefficient layer stacked with the lower piezoelectric coefficient layer and having a second piezoelectric coefficient higher than the first piezoelectric coefficient.

12. The piezoelectric composite stack of claim 11, wherein the number of n is equal to 2a, and a is an integer greater than zero, the number of the lower piezoelectric coefficient layer of the piezoelectric composite stack is an integer (i) that is equal to n, and the number of the at least one higher piezoelectric coefficient layer of the piezoelectric composite stack is an integer (j) that is equal to n.

13. The piezoelectric composite stack of claim 11, wherein the number of n is equal to 2a-1, and a is an integer greater than zero, the number of the lower piezoelectric coefficient layer of the piezoelectric composite stack is an integer (i) that is equal to n, and the number of the at least one higher piezoelectric coefficient layer of the piezoelectric composite stack is an integer (j) that is equal to n+1.

14. The piezoelectric composite stack of claim 11, wherein the number of n is 1, and the piezoelectric film comprises two higher piezoelectric coefficient layers respectively stacked above and under the lower piezoelectric coefficient layer.

15. The piezoelectric composite stack of claim 11, wherein the number of n is 2, and the piezoelectric composite stack comprises an upper piezoelectric film and a lower piezoelectric film, wherein the upper piezoelectric film comprises a (2-2)-th higher piezoelectric coefficient layer stacked above a (2-1)-th lower piezoelectric coefficient layer, the lower piezoelectric film comprises a (1-2)-th higher piezoelectric coefficient layer stacked under a (1-1)-th lower piezoelectric coefficient layer, and one of the plurality of electrode layers is disposed between the upper piezoelectric film and the lower piezoelectric film, the (2-2)-th and the (1-2)-th higher piezoelectric coefficient layers have the second piezoelectric coefficient, and the (2-1)-th and the (1-1)-th lower piezoelectric coefficient layers have the first piezoelectric coefficient.

16. The piezoelectric composite stack of claim 11, wherein the number of n is 3, and the piezoelectric composite stack comprises an upper piezoelectric film, a middle piezoelectric film and a lower piezoelectric film, wherein the upper piezoelectric film comprises a (2-2)-th higher piezoelectric coefficient layer stacked above a (2-1)-th lower piezoelectric coefficient layer, the middle piezoelectric film comprises two (3-2)-th higher piezoelectric coefficient layers sandwiching a (3-1)-th lower piezoelectric coefficient layer, the lower piezoelectric film comprises a (1-2)-th higher piezoelectric coefficient layer stacked under a (1-1)-th lower piezoelectric coefficient layer, two of the plurality of electrode layers sandwich the middle piezoelectric film, the (3-2)-th, the (2-2)-th and the (1-2)-th higher piezoelectric coefficient layers have the second piezoelectric coefficient, and the (3-1)-th, the (2-1)-th and the (1-1)-th lower piezoelectric coefficient layers have the first piezoelectric coefficient.

17. The piezoelectric composite stack of claim 16, wherein the middle piezoelectric film has a thickness different from both the thickness of the upper piezoelectric film and the thickness of the lower piezoelectric film.

18. The piezoelectric composite stack of claim 11, wherein a total thickness of the at least one higher piezoelectric coefficient layer in each the piezoelectric film is less than 50% of a total thickness of each the piezoelectric film.

19. The piezoelectric composite stack of claim 11, being symmetric with respect to a horizontal plane in the middle of the piezoelectric composite stack.

20. The piezoelectric composite stack of claim 11, wherein the composition of the lower piezoelectric coefficient layer comprises aluminum nitride (AlN), zinc oxide (ZnO), or gallium nitride (GaN), and the composition of the higher piezoelectric coefficient layer comprises lead zirconate titanate (PZT), or AlN, ZnO or GaN doped with a dopant, and wherein the dopant comprises scandium (Sc), yttrium (Y), titanium (Ti), chromium (Cr), magnesium (Mg) or hafnium (Hf).
